(19) United States
(12) Patent Application Publication
(10) Pub. No.: US 2015/0103593 A1
(43) Pub. Date: Apr. 16, 2015

(54) Method of Writing Data in Non-Volatile Memory and Non-Volatile Storage Device Using the Same

(71) Applicant: Skymedi Corporation, Hsinchu (TW)

(72) Inventor: Chien-Chang Su, Hsinchu (TW)

(73) Assignee: Skymedi Corporation, Hsinchu (TW)

(21) Appl. No.: 14/142,927

(22) Filed: Dec. 30, 2013

Related U.S. Application Data
(60) Provisional application No. 61/890,860, filed on Oct. 14, 2013.

(51) Int. Cl. G11C 16/34; G11C 29/52

(52) U.S. Cl. CPC G11C 16/3422; G11C 29/52
USPC 365/185.02

(57) ABSTRACT

A method of writing data in a non-volatile memory includes writing data from a first memory unit to a second memory unit of the non-volatile memory; checking a health of the second memory unit to generate a health result; and reserving the data in the first memory unit and mapping information corresponding to the first memory unit when the health result indicates that the second memory unit is unhealthy.

### CROSS REFERENCE TO RELATED APPLICATIONS

This application claims the benefit of U.S. Provisional Application No. 61/890,860, filed on Oct. 14, 2013 and entitled “Method to Enhance the Reliability in a Non-volatile Memory System”, the contents of which are incorporated herein by reference.

### BACKGROUND OF THE INVENTION

1. Field of the Invention

The present invention relates to a method of writing data in a non-volatile memory and a non-volatile storage device using the same, and more particularly, to a method of writing data in a non-volatile memory capable of enhancing the reliability and endurance of the non-volatile memory and a non-volatile storage device using the same.

2. Description of the Prior Art

A memory controller is commonly utilized for task management in a memory system, especially in a non-volatile memory system. In general, since data stored in a non-volatile memory system may not be lost after electric power of the non-volatile memory system is cut off, the non-volatile memory system becomes an important means to store system data. Among those non-volatile memory systems, the NAND flash memory, which has advantages of low power and high speed, becomes popular with the popularization of portable devices in recent years.

In order to reduce cost and area of the NAND flash memory, the storage capacity per unit of area in the NAND flash memory keeps increasing by using advanced process, increasing bit numbers per cell, and using 3D storage structures. Such evolution causes severe disturbances on the data stored in the NAND flash memory, and thus reliability of the data is reduced.

The memory controller plays an important role in enhancing the reliability. Error correcting codes (ECC) and threshold voltage tuning are techniques commonly utilized for correcting the data. These techniques always recover data when reading the data. Even if the ECC or voltage tuning capability is powerful, there is still a possibility that data may not be recovered. If the data recovery process fails, the accurate data may be lost, such that the reliability of the NAND flash memory will be reduced. Thus, there is a need for improvement over the prior art.

### SUMMARY OF THE INVENTION

It is therefore an objective of the present invention to provide a method of writing data in a non-volatile memory capable of enhancing the reliability and endurance of the non-volatile memory.

The present invention discloses a method of writing data in a non-volatile memory. The method comprises writing data from a first memory unit to a second memory unit of the non-volatile memory; checking a health of the second memory unit to generate a health result; and reserving the data in the first memory unit and mapping information corresponding to the first memory unit when the health result indicates that the second memory unit is unhealthy.

The present invention further discloses a non-volatile storage device. The non-volatile storage device comprises a non-volatile memory and a memory controller. The memory controller, coupled to the non-volatile memory, is utilized for writing data in the non-volatile memory by executing the following steps: writing data from a first memory unit to a second memory unit of the non-volatile memory; checking a health of the second memory unit to generate a health result; and reserving the data in the first memory unit and mapping information corresponding to the first memory unit when the health result indicates that the second memory unit is unhealthy.

The present invention further discloses a method of writing data in a non-volatile memory. The method comprises writing data from a first memory unit to a second memory unit of the non-volatile memory according to a writing strategy; checking a health of the second memory unit to generate a health result; reserving the data in the first memory unit and mapping information corresponding to the first memory unit when the health result indicates that the second memory unit is unhealthy; and modifying the writing strategy according to the health result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a non-volatile storage device according to an embodiment of the present invention.

FIG. 2 is a writing process according to an embodiment of the present invention.

FIG. 3A is a schematic diagram of data moved inside the non-volatile memory according to an embodiment of the present invention.

FIG. 3B is a schematic diagram of data moved from an external memory to the non-volatile memory according to an embodiment of the present invention.

FIG. 4 is a schematic diagram of a writing process in which different writing strategies are applied according to an embodiment of the present invention.

### DETAILED DESCRIPTION

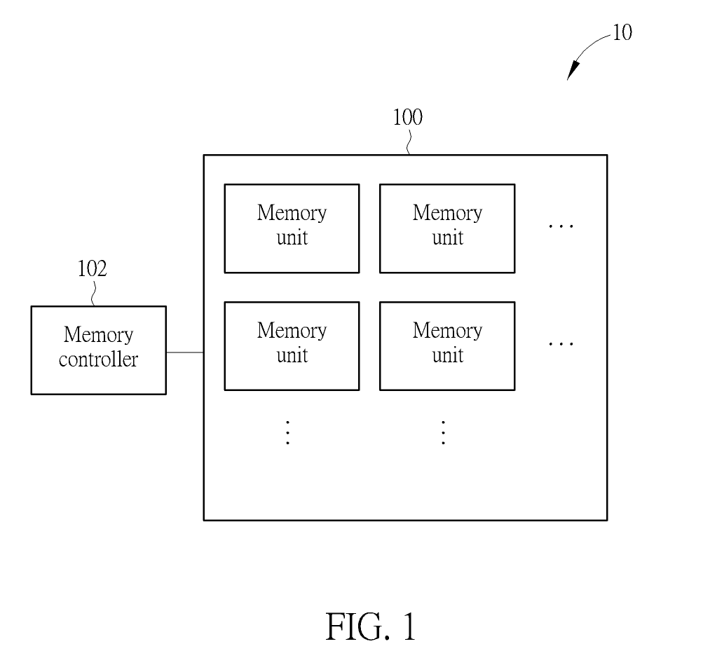

Please refer to FIG. 1, which is a schematic diagram of a non-volatile storage device 10 according to an embodiment of the present invention. As shown in FIG. 1, the non-volatile storage device 10 includes a non-volatile memory 100 and a memory controller 102. The non-volatile memory 100 includes a plurality of memory units, wherein each memory unit may be a block, a page or a cluster according to the mapping unit defined by the memory controller 102. The memory controller 102, coupled to the non-volatile memory 100, is utilized for writing data in the non-volatile memory 100 and managing the non-volatile memory 100. The memory controller 102 includes a flash translation layer (FTL) for managing the mapping information corresponding to each memory unit of the non-volatile memory 100. The memory controller 102 may also manage the strategy for writing data in each memory unit, e.g. various types of error correcting codes (ECC) or different programming methods.

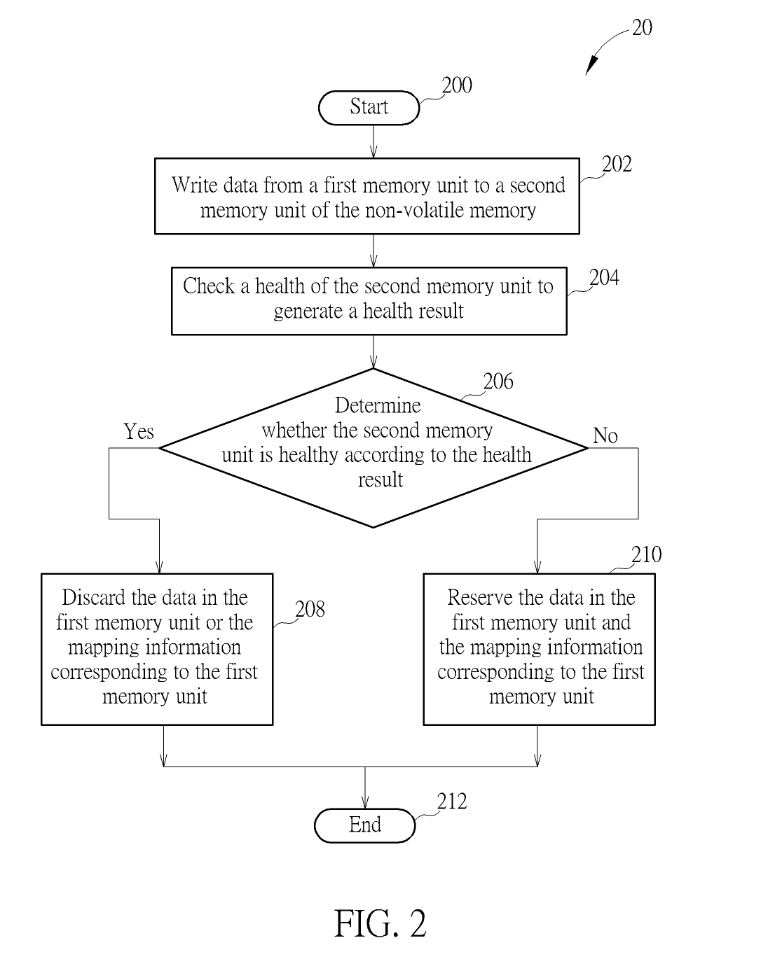

Please refer to FIG. 2, which is a writing process 20 according to an embodiment of the present invention. As shown in FIG. 2, the writing process 20, which may be realized by the memory controller 102 of the non-volatile storage device 10, includes the following steps:

Step 200: Start.

Step 202: Write data from a first memory unit to a second memory unit of the non-volatile memory.

Step 204: Check a health of the second memory unit to generate a health result.

Step 206: Determine whether the second memory unit is healthy according to the health result. If yes, go to 208; otherwise, go to 210.

Step 208: Discard the data in the first memory unit or the mapping information corresponding to the first memory unit.

Step 210: Reserve the data in the first memory unit and the mapping information corresponding to the first memory unit.

Step 212: End.

In general, the data in the first memory unit or the mapping information corresponding to the first memory unit is always discarded after the data is written into the second memory unit, but in the writing process 20, the data in the first memory unit or the mapping information corresponding to the first memory unit is discarded only when the data is written into the second memory unit and the second memory unit is determined to be healthy.

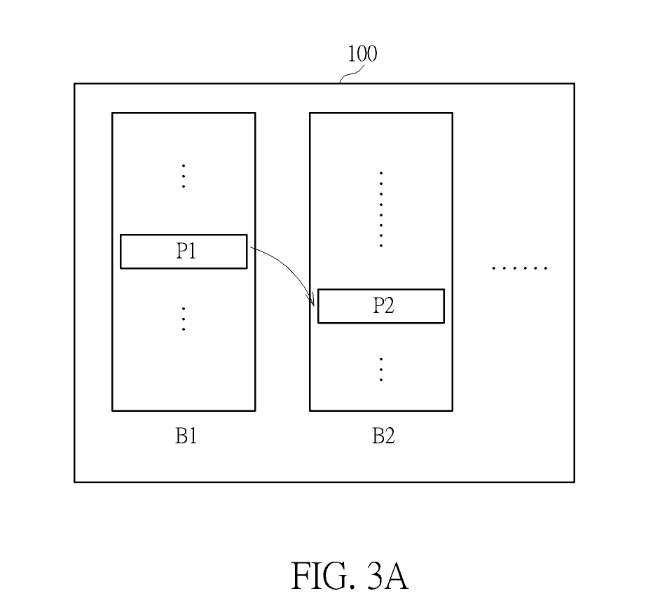

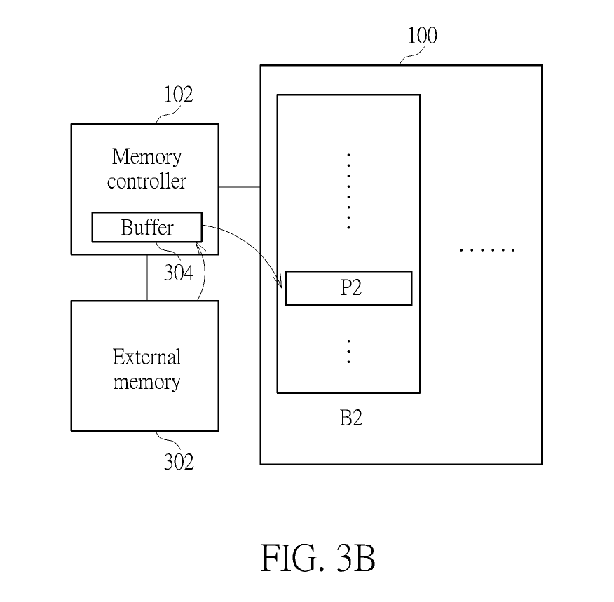

In Step 202, there is data moved from a first memory unit to a second memory unit of the non-volatile memory. The data may be moved inside the non-volatile memory 100 or moved from external memories. Please refer to FIG. 3A and FIG. 3B, where FIG. 3A is a schematic diagram of data moved inside the non-volatile memory 100 according to an embodiment of the present invention, and FIG. 3B is a schematic diagram of data moved from an external memory 302 to the non-volatile memory 100 according to an embodiment of the present invention. As shown in FIG. 3A, a page of data is moved from a memory page P1 of a memory block B1 to a memory page P2 of a memory block B2. The moving operations may include reading the data from the memory page P1, writing the data into the memory page P2 and updating the mapping information corresponding to the memory page P2. The data may be moved inside the non-volatile memory 100 due to garbage collection or wear-leveling operations. As shown in FIG. 3B, a page of data is moved from the external memory 302 to the memory page P2 of the memory block B2 in the non-volatile memory 100. The memory controller 102 may include a buffer 304, which is utilized for storing the page of data. The data is then written into the memory page P2 by the memory controller 102.

In Step 204, a health of the second memory unit is checked and a health result is generated. As shown in FIG. 3A and FIG. 3B, after data is written into the memory page P2, the health of the memory page P2 may be checked, and the corresponding health result may be generated. When there is data stored in the memory page P2, the health of the memory page P2 may be checked by reading the data stored in the memory page P2. Please note that, health check may be performed at any time. For example, the memory controller 102 may perform health check each time when data is written into the memory page P2, or perform health check at regular intervals. In such a condition, the health result may be obtained by the health check for the present data in the memory page P2 or the latest health check for previous data in the memory page P2. In an embodiment, health check may be performed when the memory controller 102 is idle, where the memory controller 102 may find several frequently used memory blocks or memory pages to perform health check in idle time and record the health results corresponding to these memory blocks or memory pages. The memory controller 102 may use a management table to record the health result of each memory unit.

In Step 206, whether the second memory unit is healthy is determined according to the health result. In an embodiment, the health status of a memory unit may be determined according to an error rate of the memory unit. The memory controller 102 may determine whether the error rate of the memory unit is greater than a threshold, in order to check the health status of the memory unit. If the error rate of the memory unit is greater than a threshold, the memory unit is determined to be unhealthy; if the error rate of the memory unit is smaller than the threshold, the memory unit is determined to be healthy. It is intuitive to consider the error rate as a number of error bit in the memory unit, and the threshold may be determined to be a specific error bit number that can still be recovered by an available ECC technique. For example, if the available ECC engine is capable of correcting up to 20 error bits in a memory unit, the threshold may be determined to be an error bit number less than 20, e.g. 14 or 16, according to reliability requirements. In another embodiment, the health of a memory unit may be determined according to an iteration number of an ECC technique for the data written in a memory unit. For example, if a specific ECC technique can recover data within 20 iterations, the threshold may be determined to be a number of iterations smaller than 20, e.g. 14. In such a condition, if the data stored in the memory unit can be recovered by the specific ECC technique within 14 iterations, the memory unit will be determined to be healthy; otherwise, if the data cannot be recovered within 14 iterations, the memory unit will be determined to be unhealthy.

In Steps 208 and 210, the data is discarded or reserved according to whether the second memory unit is healthy. As shown in FIG. 3A and FIG. 3B, after the data is written into the memory page P2 and the health information of the memory page P2 is obtained, the memory controller 102 may determine whether to discard or reserve the data in the source memory unit (e.g. the data in the memory page P1 or the external memory 302). In FIG. 3A, if the memory page P2 is determined to be unhealthy, the data in the memory page P1 and the mapping information corresponding to the memory page P1 should both be reserved, in order to keep access to the data in the memory page P1. When the memory controller 102 needs to read the data in the memory page P2 but the correct data cannot be recovered since the health of the memory page P2 is poor, the memory controller 102 may find the correct data from the memory page P1. In FIG. 3B, the data stored in the external memory 302 may not be managed by the memory controller 102. If the memory page P2 is determined to be unhealthy, the memory controller 102 may allocate another memory page in the non-volatile memory 100 and write the data from the external memory 302 or the buffer 304 to this memory page. When the memory controller 102 needs to read the data in the memory page P2 but the correct data cannot be recovered since the health of the memory page P2 is poor, the memory controller 102 may find the correct data from this memory page. When the accurate data can still be found in the source memory unit while it cannot be recovered or fixed from the destination memory unit, the reliability and endurance of the non-volatile memory 100 can be enhanced.

Please note that, the present invention provides a method of writing data in a non-volatile memory capable of enhancing the reliability and endurance of the non-volatile memory by reserving the data in the source memory unit and mapping information corresponding to the source memory unit when the destination memory unit is unhealthy. Those skilled in the art can make modifications and alternations accordingly. For example, in order to achieve the balance between reliability and writing performance, the writing process 20 may be incorporated with different writing strategies according to the health result of the memory unit.

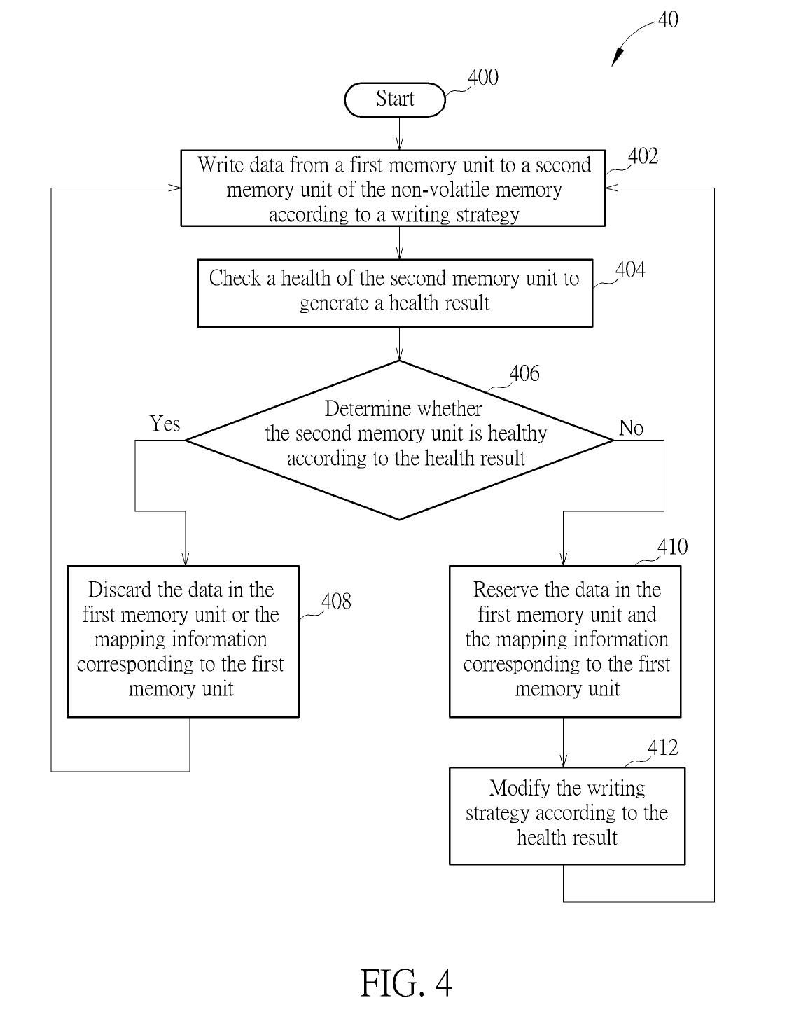

Please refer to FIG. 4, which is a schematic diagram of a writing process 40 in which different writing strategies are applied according to an embodiment of the present invention. As shown in FIG. 4, the writing process 40, which may be realized by the memory controller 102 of the non-volatile storage device 10, includes the following steps:

Step 400: Start.

Step 402: Write data from a first memory unit to a second memory unit of the non-volatile memory according to a writing strategy.

Step 404: Check a health of the second memory unit to generate a health result.

Step 406: Determine whether the second memory unit is healthy according to the health result. If yes, go to 408; otherwise, go to 410.

Step 408: Discard the data in the first memory unit or the mapping information corresponding to the first memory unit, and go to Step 402.

Step 410: Reserve the data in the first memory unit and the mapping information corresponding to the first memory unit.

Step 412: Modify the writing strategy according to the health result, and go to Step 402.

According to the writing process 40, a writing strategy may be applied to write data into the second memory unit of the non-volatile memory, and the writing strategy may be modified according to the health result. When data is written from the first memory unit to the second memory unit of the non-volatile memory 100 according to a writing strategy, the memory controller 102 checks the health of the second memory unit to generate a health result or finds the health result recorded in a management table. The memory controller 102 then determines whether the second memory unit is healthy according to the health result. If the second memory unit is healthy, the data in the first memory unit or the mapping information corresponding to the first memory unit may be discarded. If the second memory unit is unhealthy, the data in the first memory unit and the mapping information corresponding to the first memory unit should be reserved, in order to keep access to the data in the first memory unit. The memory controller 102 then modifies the writing strategy for the second memory unit, in order to enhance the reliability of subsequent data in the second memory unit. If the reliability is enhanced due to a powerful writing strategy, when there is new data written into the second memory unit via this powerful writing strategy, reservation of the source data may not be required.

Please note that, different writing strategies are applied in response to different health status. When the health status of a memory unit becomes worse, a more powerful writing strategy for enhancing reliability should be applied to compensate for the health status of the memory unit. Different writing strategies may include different ECC capabilities such as BCH codes and low-density parity-check (LDPC) codes. For example, a basic ECC engine, BCH40, may be applied when a memory unit starts to be in use and the error rate of the memory unit is low. The basic ECC engine may achieve higher writing speed, lower power consumption, lower memory space occupation and better performance when providing enough reliability. When the health status of the memory unit gets worse and the error rate increases to be higher than a threshold, a powerful ECC engine such as BCH70 or BCH100 may be utilized for enhancing reliability and endurance. Furthermore, if the memory unit wears out and includes more error bits, a higher level ECC engine such as BCH140 or LDPC may be utilized for correcting more error bits. It is worth mentioned that the threshold for determining the health of the memory unit may be varied according to different writing strategies. For example, if an ECC engine is capable of correcting 20 error bits in the memory unit, the corresponding threshold may be 14 error bits; if an ECC engine is capable of correcting 40 error bits in the memory unit, the corresponding threshold may be 28 error bits.

Noticeably, when the higher level ECC is applied, more buffer space is required for storing the parity codes for error correction. Sometimes the parity codes are longer than whole storage space of the memory unit; hence it is desirable to reserve a memory space for storing these parity codes. When the memory unit 100 is healthy, the reserved memory space may be used as extra read/write buffer to enhance system throughput. When the health status of the memory unit 100 gets worse, this reserved memory space may be utilized for storing the parity bits required for enhancing the reliability and endurance.

Please note that the step of reserving data in the source memory unit (Step 410) and the step of modifying the writing strategy (Step 412) are both capable of enhancing reliability. Only the step of reserving data in the source memory unit is feasible for enhancing reliability of the present data. Since data is already written into the memory unit before the health of this memory unit is checked, the new strategy should be applied for subsequent writing process in this memory unit.

In an embodiment, the writing strategies may include different level numbers of a multi-level cell (MLC) configuration. For example, if a memory unit having MLC configuration is determined to be unhealthy, the memory controller may reconfigure this memory unit to store data using single-level cell (SLC) configuration. The reliability and endurance can therefore be achieved since the voltage different for data determination is enlarged, but storage capacity of the memory unit may be sacrificed. In another embodiment, the writing strategies may also include programming dummy data in at least one page of a memory unit. For example, if a memory unit with MLC configuration has two memory pages and the memory unit is determined to be unhealthy, the memory controller may program dummy data in the most significant bit (MSB) page or the least significant bit (LSB) page of the memory unit. The reliability and endurance can therefore be achieved since data is not easily interfered with by the other page of data. Please note that, different writing strategies, including but not limited to different ECC engines, different cell configurations, dummy data programming, and other possible reliability enhancing strategies, may be applied together to achieve different levels of reliability enhancing capabilities according to system requirements.

In the prior art, ECC and threshold voltage tuning techniques always recover data when reading the data. Even if the ECC or voltage tuning capability is powerful, it is still a possibility that data may not be recovered. If the data recovery process fails, the accurate data may be lost, such that the reliability and endurance of the non-volatile memory will be reduced. In comparison, the present invention provides a method of writing data in a non-volatile memory and a non-volatile storage device capable of reserving data in the source memory unit and mapping information corresponding to the source memory unit when writing data into the destination memory unit and determining that the destination memory unit is unhealthy. When the correct data cannot be recovered since the health of destination memory unit is poor, it can still be found in the source memory unit, which enhances the reliability and endurance of the non-volatile memory.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of writing data in a non-volatile memory, comprising:
writing data from a first memory unit to a second memory unit of the non-volatile memory;
checking a health of the second memory unit to generate a health result; and
reserving the data in the first memory unit and mapping information corresponding to the first memory unit when the health result indicates that the second memory unit is unhealthy.

2. The method of claim 1, further comprising:
discarding the data in the first memory unit or the mapping information corresponding to the first memory unit when the health result indicates that the second memory unit is healthy.

3. The method of claim 1, wherein the step of checking the health of the second memory unit to generate the health result comprises:
determining whether an error rate of the second memory unit is greater than a threshold.

4. The method of claim 3, wherein the error rate of the second memory unit is a number of error bit in the second memory unit or an iteration number of an error correction for the data written into the second memory unit.

5. The method of claim 1, further comprising:
recording the health result of the second memory unit.

6. The method of claim 5, further comprising:
applying a writing strategy to the second memory unit according to the recorded health result.

7. The method of claim 1, further comprising:
writing the data from the first memory unit to a third memory unit of the non-volatile memory when the second memory unit is unhealthy and the first memory unit is outside the non-volatile memory.

8. A non-volatile storage device, comprising:
a non-volatile memory; and
a memory controller, coupled to the non-volatile memory, for writing data in the non-volatile memory by executing the following steps:
writing data from a first memory unit to a second memory unit of the non-volatile memory;
checking a health of the second memory unit to generate a health result; and
reserving the data in the first memory unit and mapping information corresponding to the first memory unit when the health result indicates that the second memory unit is unhealthy.

9. The non-volatile storage device of claim 8, wherein the memory controller further executes the following step to write data in the non-volatile memory:
discarding the data in the first memory unit or the mapping information corresponding to the first memory unit when the health result indicates that the second memory unit is healthy.

10. The non-volatile storage device of claim 8, wherein the step of checking the health of the second memory unit to generate the health result comprises:
determining whether an error rate of the second memory unit is greater than a threshold.

11. The non-volatile storage device of claim 10, wherein the error rate of the second memory unit is a number of error bit in the second memory unit or an iteration number of an error correction for the data written into the second memory unit.

12. The non-volatile storage device of claim 8, wherein the memory controller further executes the following step to write data in the non-volatile memory:
recording the health result of the second memory unit.

13. The non-volatile storage device of claim 12, wherein the memory controller further executes the following step to write data in the non-volatile memory:
applying a writing strategy to the second memory unit according to the recorded health result.

14. The non-volatile storage device of claim 8, wherein the memory controller further executes the following step to write data in the non-volatile memory:
writing the data from the first memory unit to a third memory unit of the non-volatile memory when the second memory unit is unhealthy and the first memory unit is outside the non-volatile memory.

15. A method of writing data in a non-volatile memory, comprising:
writing data from a first memory unit to a second memory unit of the non-volatile memory according to a writing strategy;
checking a health of the second memory unit to generate a health result;
reserving the data in the first memory unit and mapping information corresponding to the first memory unit when the health result indicates that the second memory unit is unhealthy; and
modifying the writing strategy according to the health result.

16. The method of claim 15, further comprising:
discarding the data in the first memory unit or the mapping information corresponding to the first memory unit when the health result indicates that the second memory unit is healthy.

17. The method of claim 15, wherein the step of checking the health of the second memory unit to generate the health result comprises:
determining whether an error rate of the second memory unit is greater than a threshold.

18. The method of claim 17, wherein the error rate of the second memory unit is a number of error bit in the second memory unit or an iteration number of an error correction for the data written into the second memory unit.

19. The method of claim 15, wherein the step of modifying the writing strategy according to the health result comprises:
reducing a level number of a multi-level cell configuration of the second memory unit.

20. The method of claim 15, wherein the step of modifying the writing strategy according to the health result comprises:
programming dummy data in at least one page of the second memory unit.
